(19) United States
(12) Patent Application Publication
(10) Pub. No.: US 2025/0157400 A1
(43) Pub. Date: May 15, 2025

(54) POWER SELECTION CIRCUIT, DISPLAY PANEL, AND DISPLAY APPARATUS

(71) Applicants: Hefei Visionox Technology Co., Ltd., Hefei (CN); KunShan Go Visionox Opto Electronics Co., Ltd, Kunshan (CN)

(72) Inventors: Yongqiang DU, Hefei (CN); Yuan YAO, Hefei (CN); Qing BAI, Hefei (CN); Zhendong DING, Hefei (CN); Xiaoxi SUN, Hefei (CN); Bo RAO, Hefei (CN)

(73) Assignees: Hefei Visionox Technology Co., Ltd., Hefei (CN); KunShan Go Visionox Opto Electronics Co., Ltd, Kunshan (CN)

(21) Appl. No.: 18/666,999

(22) Filed: May 17, 2024

(30) Foreign Application Priority Data
Nov. 10, 2023 (CN) 202311524659.2

(51) Int. Cl. G09G 3/3233; H10K 59/121; H10K 59/131

(52) U.S. Cl. CPC G09G 3/3233; H10K 59/121; H10K 59/131; G09G 2300/0465; G09G 2300/0842; G09G 2310/08; G09G 2320/0233; G09G 2330/02

(57) ABSTRACT

A power selection circuit, a display panel, and a display apparatus. The power selection circuit includes a voltage signal line, the voltage signal line being configured to transmit a voltage signal to a first electrode of a light-emitting sub-pixel, and control at least two groups of light-emitting sub-pixels to emit light group by group. One group of light-emitting sub-pixels includes at least one row of light-emitting sub-pixels or at least one row of light-emitting sub-pixel units, and one of the light-emitting sub-pixel units includes at least two different light-emitting sub-pixels. Independent light-emitting control over each group of light-emitting sub-pixels can be realized, thereby realizing row-by-row lighting or group-by-group lighting of respective rows of light-emitting sub-pixels.

### CROSS REFERENCE TO RELATED APPLICATION

The present application claims priority to Chinese Patent Application No. 202311524659.2 filed on Nov. 10, 2023, and titled “POWER SELECTION CIRCUIT, DISPLAY PANEL, AND DISPLAY APPARATUS”, which is incorporated herein by reference in its entirety.

### TECHNICAL FIELD

The present application relates to the technical field of display, and in particular, to a power selection circuit, a display panel, and a display apparatus.

### BACKGROUND

An organic light emitting display (OLED) and a flat display apparatus based on a light emitting diode (LED) technology are widely used in various consumer electronic products such as mobile phones, TVs, notebook computers, and desktop computers due to advantages such as high image quality, power saving, a thin body, and a wide range of applications, becoming the mainstream in display apparatuses.

However, operational performance of current OLED display products needs to be improved.

### SUMMARY

Embodiments of the present application provide a power selection circuit, a display panel, and a display apparatus, which can solve the technical problem in the prior art that different refresh frequencies cannot be used for driving during split-screen display of various regions.

In a first aspect, an embodiment of the present application provides a power selection circuit, including a voltage signal line, the voltage signal line being configured to transmit a voltage signal to a first electrode of a light-emitting sub-pixel, and control at least two groups of light-emitting sub-pixels to emit light group by group;
wherein one group of light-emitting sub-pixels includes at least one row of light-emitting sub-pixels or at least one row of light-emitting sub-pixel units, and one of the light-emitting sub-pixel units includes at least two different light-emitting sub-pixels.

In a second aspect, an embodiment of the present application provides a display panel, including the power selection circuit in the first aspect, and
a plurality of groups of light-emitting sub-pixels arranged in an array, each group of light-emitting sub-pixels including at least one row of light-emitting sub-pixels or at least one row of light-emitting sub-pixel units, one of the light-emitting sub-pixel units including at least two different light-emitting sub-pixels, first electrodes of the light-emitting sub-pixels in a same group being electrically connected, and first electrodes of the light-emitting sub-pixels in different groups being insulated from each other;
one power selection circuit being connected to the first electrodes of one group of light-emitting sub-pixels.

In a third aspect, an embodiment of the present application provides a display apparatus, including the display panel in the second aspect.

Compared with the prior art, according to the power selection circuit, the display panel, and the display apparatus provided in the embodiments of the present application, the voltage signal line is arranged to transmit a voltage signal to a first electrode of a light-emitting sub-pixel, which can transmit voltage signals to the light-emitting sub-pixels in a same group. By controlling time intervals during which different groups of light-emitting sub-pixels receive the voltage signals, various groups of light-emitting sub-pixels can emit light group by group. In the display panel, when the voltage signal line is arranged, independent light-emitting control over each group of light-emitting sub-pixels can be realized through the voltage signal line, thereby realizing row-by-row lighting or group-by-group lighting of respective rows of light-emitting sub-pixels.

### BRIEF DESCRIPTION OF THE DRAWINGS

In order to more clearly illustrate the technical solutions in embodiments of the present application, the accompanying drawings to be used in the description of the embodiments of the present application will be briefly introduced below. Obviously, the accompanying drawings described below are only some embodiments of the present application. For those of ordinary skill in the art, other accompanying drawings can also be obtained from the provided drawings without creative efforts.

FIG. 1 is a schematic diagram of a modular structure of a power selection circuit according to an embodiment of the present application;

FIG. 2 is a schematic diagram of a modular structure of the power selection circuit according to another embodiment of the present application;

FIG. 3 is a signal timing diagram of the power selection circuit in FIG. 1;

FIG. 4 is a signal timing diagram of the power selection circuit in FIG. 2;

FIG. 5 is a schematic diagram of a modular structure of the power selection circuit according to yet another embodiment of the present application;

FIG. 6 is a schematic diagram of a circuit structure of light-emitting sub-pixels according to an embodiment of the present application;

FIG. 7 is a schematic structural diagram of mutual isolation of first electrodes of two adjacent rows of light-emitting sub-pixels according to an embodiment of the present application;

FIG. 8 is a schematic diagram of a partial layer structure of light-emitting sub-pixels according to an embodiment of the present application;

FIG. 9 is a schematic diagram of a circuit structure of the power selection circuit according to an embodiment of the present application;

FIG. 10 is a signal timing diagram of the power selection circuit in FIG. 9;

FIG. 11 is a schematic diagram of a modular structure of the power selection circuit according to still another embodiment of the present application;

FIG. 12 is a schematic diagram of a circuit structure of the power selection circuit according to another embodiment of the present application;

FIG. 13 is a signal timing diagram of the power selection circuit in FIG. 12;

FIG. 14 is a schematic diagram of a circuit structure of the power selection circuit according to another embodiment of the present application;

FIG. 15 is a signal timing diagram of the power selection circuit in FIG. 14;

FIG. 16 is a schematic diagram of a circuit structure of a display panel according to an embodiment of the present application;

FIG. 17 is a signal timing diagram corresponding to FIG. 16;

FIG. 18 is a schematic diagram of a circuit structure of the display panel according to another embodiment of the present application;

FIG. 19 is a signal timing diagram corresponding to FIG. 15;

FIG. 20 is a schematic diagram of a circuit structure of the display panel according to yet another embodiment of the present application;

FIG. 21 is a signal timing diagram corresponding to FIG. 20;

FIG. 22 is a schematic diagram of signal timing of a single light-emitting frame in the related art;

FIG. 23 is a schematic diagram of light-emitting states of respective rows of light-emitting sub-pixels in the embodiments in FIG. 22;

FIG. 24 is a schematic diagram of signal timing of the single light-emitting frame according to an embodiment of the present application;

FIG. 25 is a schematic diagram of light-emitting states of respective rows of light-emitting sub-pixels in the embodiments in FIG. 24;

FIG. 26 is a schematic diagram of signal timing of the single light-emitting frame according to another embodiment of the present application;

FIG. 27 is a schematic diagram of light-emitting states of respective rows of light-emitting sub-pixels in the embodiments in FIG. 26;

FIG. 28 is a schematic diagram of a simulation waveform according to an embodiment of the present application; and

FIG. 29 is a schematic structural diagram of a display apparatus according to an embodiment of the present application.

In the drawings,

1. power selection module; 11. first signal module; 12. second signal module; 20. light-emitting sub-pixel; 21. pixel driving circuit; L. light-emitting element; ELVSS. first voltage signal line; EM. first control signal line; T1. first transistor; T2. second transistor.

### DETAILED DESCRIPTION

Features and exemplary embodiments in various aspects of the present application will be described in detail below. To make the objectives, technical solutions, and advantages of the present application clearer, the present application will be further described in detail below with reference to the accompanying drawings and specific embodiments. It should be understood that the specific embodiments described herein are merely configured to explain the present application, rather than to limit the present application. For those skilled in the art, the present application can be implemented without some of these specific details. The following description of the embodiments is merely to provide a better understanding of the present application by illustrating the examples of the present application.

It is to be noted that the relationship terms used herein, such as first and second, are only used to distinguish one entity or operation from another entity or operation, but do not necessarily require or imply that there is such an actual relationship or order between these entities or operations. Moreover, the terms “include”, “comprise”, or any variants thereof are intended to cover a non-exclusive inclusion, such that processes, methods, articles, or devices, including a series of elements, include not only those elements that have been listed, but also other elements that have not specifically been listed or the elements intrinsic to these processes, methods, articles, or devices. Without more limitations, elements limited by the wording “comprise(s)/include(s) a/an . . . ” do not exclude additional identical elements in the processes, methods, articles, or devices including the listed elements.

It is to be noted that embodiments and features in the embodiments in the present application can be combined with each other without any conflict. The embodiments will be described in detail below with reference to the accompanying drawings.

An OLED and a flat display apparatus based on a LED technology are widely used in various consumer electronic products such as mobile phones, TVs, notebook computers, and desktop computers due to advantages such as high image quality, power saving, a thin body, and a wide range of applications, becoming the mainstream in display apparatuses. However, operational performance of current OLED display products needs to be improved.

With the consecutive development of the field of display technologies, requirements for pixels per inch (PPI, pixel density unit) of UIs and display apparatuses have gradually increased. Within a display screen of a same size, if a higher PPI is to be achieved, there is a need to reduce an area of a single light-emitting sub-pixel. Since the single light-emitting sub-pixel generally includes a pixel driving circuit and a light-emitting element, in order to reduce the area of the light-emitting sub-pixel, there is generally a need to reduce a number of transistors accommodated in the pixel driving circuit. That is, in a display panel product with a higher PPI, a number of transistors included in a pixel driving circuit may generally be lower than a number of transistors in a current more conventional pixel driving circuit.

However, a reduction in the number of transistors in the pixel driving circuit will be accompanied by loss of corresponding functions. After the transistors configured to achieve row-by-row light emission of pixels in the conventional pixel driving circuit are eliminated, respective rows of pixels in the display panel will no longer achieve row-by-row light emission of the pixels.

In order to solve the above technical problems, embodiments of the present application provided a power selection circuit, a display panel, and a display apparatus. The display panel provided in the embodiments of the present application is first introduced below.

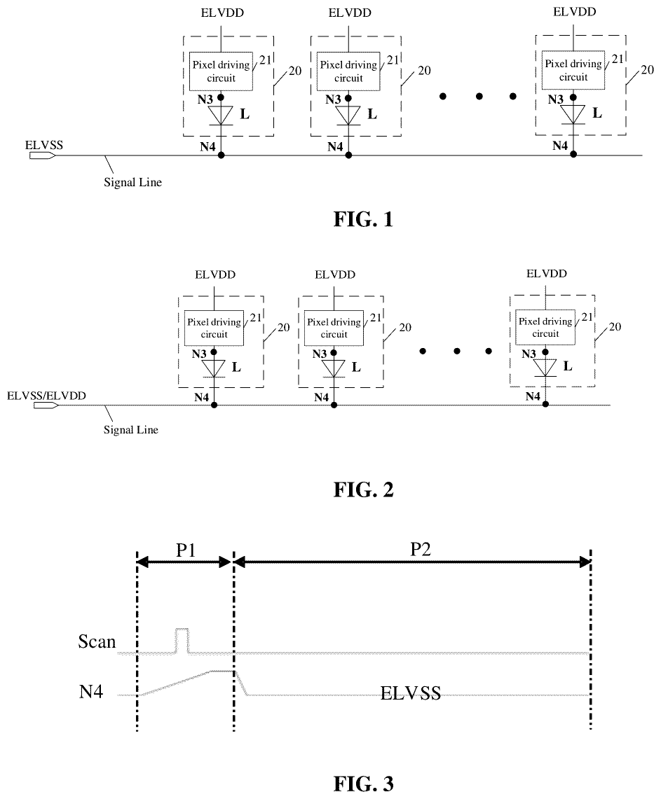

FIG. 1 is a schematic diagram of a circuit structure of a power selection circuit according to an embodiment of the present application. The power selection circuit includes a voltage signal line. The voltage signal line may transmit a voltage signal to a first electrode of a light-emitting sub-pixel 20.

In the light-emitting sub-pixels 20 arranged in an array in the display panel, a plurality of light-emitting sub-pixels 20 may be classified into light-emitting sub-pixel groups. One group of light-emitting sub-pixels 20 includes at least one row of light-emitting sub-pixels 20 or at least one row of light-emitting sub-pixel units. One light-emitting sub-pixel unit may include at least two different light-emitting sub-pixels. The voltage signal line may control at least two groups of light-emitting sub-pixels 20 to emit light group by group.

When the voltage signal line does not transmit a voltage signal to the first electrode of the light-emitting sub-pixel 20, a voltage difference between a second electrode and the first electrode of the light-emitting sub-pixel 20 will be less than a turn-on voltage of the light-emitting sub-pixel 20. In this case, the light-emitting sub-pixel 20 does not emit light.

For example, as shown in FIG. 1, Signal Line is the voltage signal line, Node n4 is the first electrode of the light-emitting sub-pixel 20, and Node n3 is the second electrode of the light-emitting sub-pixel 20. When the voltage signal line transmits a voltage signal to the first electrode of the light-emitting sub-pixel 20 and the voltage difference between the second electrode and the first electrode of the light-emitting sub-pixel 20 is greater than the turn-on voltage of the light-emitting sub-pixel 20, the light-emitting sub-pixel 20 will emit light.

When the voltage signal line provides voltage signals for a same group of light-emitting sub-pixels 20, a plurality of light-emitting sub-pixels 20 in the same group can emit light or go out simultaneously. By adjusting the time at which the voltage signal line transmits voltage signals to different groups of light-emitting sub-pixels 20, the light-emitting time of the different groups of light-emitting sub-pixels 20 can be staggered, thereby achieving group-by-group light emission of the groups of light-emitting sub-pixels 20.

It may be understood that one group of light-emitting sub-pixels 20 may include at least one row of light-emitting sub-pixels 20. When each group of light-emitting sub-pixels 20 includes a single row of light-emitting sub-pixels 20, the rows of light-emitting sub-pixels 20 can emit light row by row. When each group of light-emitting sub-pixels 20 includes more than two rows of light-emitting sub-pixels 20, the light-emitting sub-pixels 20 can emit light two rows by two rows or multiple rows by multiple rows.

For the light-emitting sub-pixels 20 that have a reduced number of transistors in pixel driving circuits 21 in order to pursue higher PPI and cannot achieve light emission and lighting row by row or multiple rows by multiple rows, the voltage signal line can individually provide the voltage signals for one or more rows of light-emitting sub-pixels 20 in a same group. When the light-emitting sub-pixel 20 is in a non-light-emitting stage, steps such as data writing and initialization are performed on the light-emitting sub-pixel 20.

In this embodiment, through the arrangement of the voltage signal line, the voltage signal can be transmitted to the first electrode of the light-emitting sub-pixel 20, so that the light-emitting sub-pixel 20 switches between the light-emitting stage and the non-light-emitting stage, thereby realizing light-emitting control over the light-emitting sub-pixel 20. By controlling the light-emitting stages of different groups of light-emitting sub-pixels 20 to be staggered from each other, the different groups of the light-emitting sub-pixels 20 can emit light group by group. In the display panel, when the voltage signal line is arranged, independent light-emitting control over each group of light-emitting sub-pixels 20 can be realized through the voltage signal line, thereby realizing row-by-row lighting or group-by-group lighting of respective rows of light-emitting sub-pixels.

In some embodiments, a voltage signal less than a difference between a second electrode voltage of the light-emitting sub-pixel 20 and a turn-on voltage of the light-emitting sub-pixel 20 may be intermittently transmitted in the above voltage signal line.

When the voltage signal line transmits the voltage signal to the first electrode of the light-emitting sub-pixel 20, a voltage difference between a second electrode and the first electrode of the light-emitting sub-pixel 20 will be greater than the turn-on voltage of the light-emitting sub-pixel 20. In this case, the light-emitting sub-pixel 20 can emit light.

There is a parasitic capacitor between the first electrode and the second electrode of the light-emitting sub-pixel 20. When the voltage signal line stops transmitting the voltage signal to the first electrode of the light-emitting sub-pixel 20, due to a characteristic that voltages at two ends of the parasitic capacitor cannot be changed suddenly, a potential of the first electrode corresponding to each light-emitting sub-pixel 20 is still a signal voltage of the voltage signal. However, as electrons stored in the parasitic capacitor continue to be recombined with holes to emit light, a voltage difference at the two ends of the parasitic capacitor will gradually decrease, so that the voltage difference between the second electrode and the first electrode of the light-emitting sub-pixel 20 gradually decreases. That is, when the voltage signal line stops transmitting the voltage signal to the first electrode of the light-emitting sub-pixel 20, the light-emitting sub-pixel 20 will gradually go out.

By intermittently transmitting the voltage signal, the voltage signal line can realize light emission of the light-emitting sub-pixel 20 when transmitting the voltage signal normally, and realize extinguishing of the light-emitting sub-pixel 20 when stopping transmitting the voltage signal.

In some embodiments, two voltage signals, that is, the voltage signal less than the difference between the second electrode voltage of the light-emitting sub-pixel 20 and the turn-on voltage of the light-emitting sub-pixel 20 and a voltage signal greater than the difference between the second electrode voltage of the light-emitting sub-pixel 20 and the turn-on voltage of the light-emitting sub-pixel 20, may be transmitted in the above voltage signal line in a time-sharing manner.

When the voltage signal transmitted by the voltage signal line is less than the difference between the second electrode voltage of the light-emitting sub-pixel 20 and the turn-on voltage of the light-emitting sub-pixel 20, the voltage difference between the second electrode and the first electrode of the light-emitting sub-pixel 20 is greater than the turn-on voltage of the light-emitting sub-pixel 20, and the light-emitting sub-pixel 20 can emit light.

When signal amplitude of the voltage signal transmitted by the voltage signal line is greater than the difference between the second electrode voltage of the light-emitting sub-pixel 20 and the turn-on voltage of the light-emitting sub-pixel 20, the voltage difference between the second electrode and the first electrode of the light-emitting sub-pixel 20 will be less than the turn-on voltage of the light-emitting sub-pixel 20. In this case, the voltage difference between the second electrode and the first electrode of the light-emitting sub-pixel 20 cannot drive the light-emitting sub-pixel 20 to emit light, and the light-emitting sub-pixel will go out.

As shown in FIG. 2, Signal Line is the voltage signal line, Node n4 is the first electrode of the light-emitting sub-pixel 20, and Node n3 is the second electrode of the light-emitting sub-pixel 20. Two voltage signals transmitted in a time-sharing manner in the voltage signal line may be ELVSS and ELVDD respectively. When the voltage signal line transmits ELVSS to the first electrode of the light-emitting sub-pixel 20 and the voltage difference between the second electrode and the first electrode of the light-emitting sub-pixel 20 is greater than the turn-on voltage of the light-emitting sub-pixel 20, that is, (Vn3−Vn4)>Von, the light-emitting sub-pixel 20 will emit light. When the voltage signal line transmits ELVDD to the first electrode of the light-emitting sub-pixel 20 and the voltage difference between the second electrode and the first electrode of the light-emitting sub-pixel 20 is less than the turn-on voltage of the light-emitting sub-pixel 20, the light-emitting sub-pixel 20 goes out.

Compared with the implementation in which the above voltage signal line transmits voltage signals intermittently, in this embodiment, the voltage signal line does not realize extinguishing of the light-emitting sub-pixel 20 by stopping transmitting the voltage signal, but by transmitting a voltage signal greater than the difference between the second electrode voltage of the light-emitting sub-pixel and the turn-on voltage of the light-emitting sub-pixel. Under the voltage signal, the potential of the first electrode of the light-emitting sub-pixel 20 can be quickly raised, so that the voltage difference between the second electrode and the first electrode of the light-emitting sub-pixel 20 is more quickly reduced to a value below the turn-on voltage. That is, a speed at which the light-emitting sub-pixel 20 goes out is increased.

In some embodiments, one group of light-emitting sub-pixels includes at least one row of light-emitting sub-pixel units, and one light-emitting sub-pixel unit includes at least two different light-emitting sub-pixels. At least part of the at least two different light-emitting sub-pixels are located in different rows. For example, when a single light-emitting sub-pixel unit includes two different light-emitting sub-pixels, the two different light-emitting sub-pixels may be located in different rows. When the single light-emitting sub-pixel unit includes three or more light-emitting sub-pixels, at least two different light-emitting sub-pixels may be located in different rows.

Referring to FIG. 3, FIG. 3 is a signal timing diagram of the power selection circuit in an implementation in which the voltage signal line intermittently transmits the voltage signal. For example, the voltage signal transmitted by the voltage signal line is ELVSS. In a P1 interval, the voltage signal line stops transmitting the voltage signal. In this case, a potential of Node n4, that is, the potential of the first electrode of the light-emitting sub-pixel 20 will gradually increase until the light-emitting sub-pixel 20 goes out. In the P1 interval, a scan signal Scan may provide a high-level pulse as an enable active signal to implement data signal writing in the non-light-emitting stage within an enable active interval.

In a P2 interval, the voltage signal line transmits a voltage signal. In this case, the potential of Node n4 is pulled down to ELVSS, and the light-emitting sub-pixel 20 emits light.

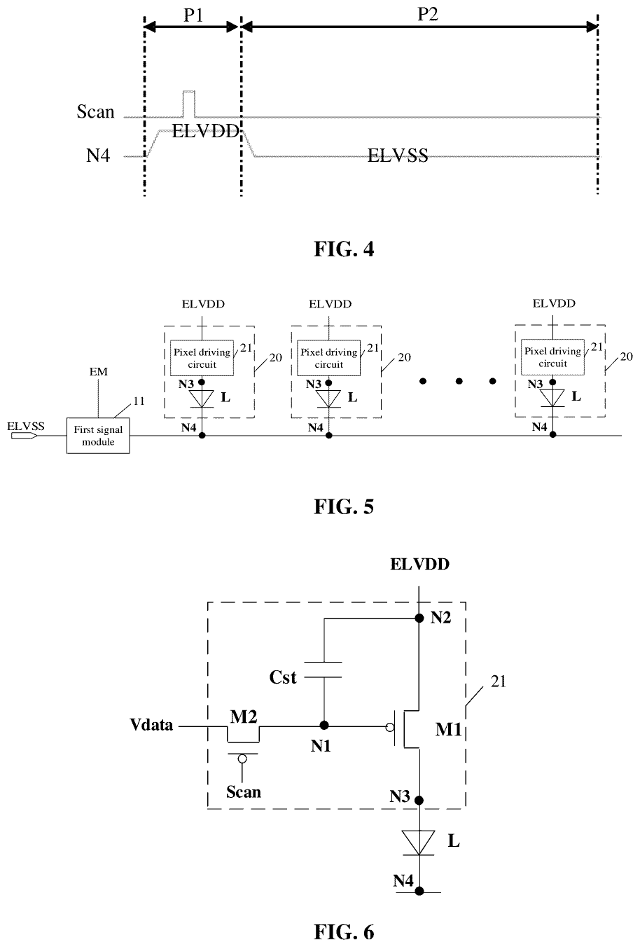

FIG. 4 is a signal timing diagram of the power selection circuit in an implementation in which the voltage signal line can transmit two voltage signals in a time-sharing manner. For example, the two voltage signals transmitted by the voltage signal line in the time-sharing manner are ELVSS and ELVDD respectively. In the P1 interval, the voltage signal line transmits ELVDD. In this case, the potential of Node n4, that is, the potential of the first electrode of the light-emitting sub-pixel 20, will be quickly raised to ELVDD, so that a voltage difference between the second electrode and the first electrode of the light-emitting sub-pixel 20 is reduced to a value less than the turn-on voltage, and the light-emitting sub-pixel 20 goes out. In the P1 interval, the scan signal Scan may provide a high-level pulse as an enable active signal to implement data signal writing in the non-light-emitting stage within an enable active interval.

In the P2 interval, the voltage signal line transmits ELVSS. In this case, the potential of Node n4 is pulled down to ELVSS, and the light-emitting sub-pixel 20 emits light.

Referring to FIG. 5, in some embodiments, the above power selection circuit may include a first signal module 11, and the voltage signal line may include a first voltage signal line ELVSS.

As shown in FIG. 9, the first signal module 11 includes a first terminal, a second terminal, and a control terminal. A first terminal of the first signal module 11 is connected to the first voltage signal line ELVSS, a second terminal of the first signal module 11 is connected to first electrodes of one group of light-emitting sub-pixels 20, and a control terminal of the first signal module 11 is connected to a first control signal line EM.

In a light-emitting stage, a voltage signal transmitted in the first voltage signal line ELVSS is less than the difference between the second electrode voltage of the light-emitting sub-pixel 20 and the turn-on voltage of the light-emitting sub-pixel 20. That is, the second electrode of the light-emitting sub-pixel 20 is an anode, and the first electrode is a cathode. In this case, the light-emitting sub-pixel 20 can emit light.

As shown in FIG. 9, the potential of N4 is a potential of the first electrode corresponding to the light-emitting sub-pixel 20. The first signal module 11 may be connected to the first electrodes corresponding to one group of light-emitting sub-pixels 20. The group of light-emitting sub-pixels 20 may be one row of light-emitting sub-pixels 20 or multiple consecutive rows of light-emitting sub-pixels 20.

For example, the display panel includes n rows of light-emitting sub-pixels 20. When each first signal module 11 is connected to the first electrodes corresponding to one row of light-emitting sub-pixels 20, n rows of light-emitting sub-pixels 20 respectively correspond to n first signal modules 11. When each first signal module 11 is connected to first electrodes corresponding to x rows of light-emitting sub-pixel 20 and x is a positive integer greater than or equal to 2, since a single first signal module 11 corresponds to x rows of light-emitting sub-pixels 20, n rows of light-emitting sub-pixels 20 correspond to (n/x) first signal modules 11.

The first electrode corresponding to the light-emitting sub-pixel 20 connected to one first signal module 11 and the first electrode corresponding to the light-emitting sub-pixel 20 connected to another first signal module 11 are insulated from each other.

For example, when the first signal module 11 is connected to the first electrodes corresponding to one row of light-emitting sub-pixels 20, the first electrodes corresponding to the group of light-emitting sub-pixels 20 and first electrodes corresponding to a previous group of light-emitting sub-pixels 20 are insulated from each other, and the first electrodes corresponding to the group of light-emitting sub-pixels 20 and first electrodes corresponding to a next group of light-emitting sub-pixels 20 are insulated from each other.

When the first signal module 11 is connected to the first electrodes corresponding to x rows of light-emitting sub-pixels 20, the first electrodes corresponding to each row of light-emitting sub-pixels 20 in the x rows of light-emitting sub-pixels 20 are electrically connected to each other, the first electrodes corresponding to the x rows of light-emitting sub-pixels 20 and first electrodes corresponding to a previous row of light-emitting sub-pixels 20 are isolated from each other, and the first electrodes corresponding to the group of light-emitting sub-pixels 20 and first electrodes corresponding to a next row of light-emitting sub-pixels 20 are isolated from each other.

For example, one group of light-emitting sub-pixels 20 includes three consecutive rows of light-emitting sub-pixels 20. When a certain first signal module 11 is connected to first electrodes corresponding to the light-emitting sub-pixels 20 in Rows 101 to 103, the first electrodes corresponding to the light-emitting sub-pixels 20 in Rows 101 to 103 are all electrically connected to each other, the first electrodes corresponding to the light-emitting sub-pixels 20 in Row 101 and first electrodes corresponding to the light-emitting sub-pixels 20 in Row 100 are insulated and isolated from each other, and the first electrodes corresponding to the light-emitting sub-pixels 20 in Row 103 and first electrodes corresponding to the light-emitting sub-pixels 20 in Row 104 are insulated and isolated from each other.

When the first signal module 11 is turned on, the first voltage signal line ELVSS may be connected to the first electrodes of the corresponding row or rows of light-emitting sub-pixels 20 through the first signal module 11. In this case, the first electrodes of the row or rows of light-emitting sub-pixels 20 can receive the voltage signal provided by the first voltage signal line ELVSS. When the second electrodes of the row or rows of light-emitting sub-pixels 20 can receive a second power signal provided by the second voltage signal line and the voltage difference between the second electrode and the first electrode of the light-emitting sub-pixel 20 is greater than the turn-on voltage of the light-emitting sub-pixel 20, that is, (Vn3−Vn4)>Von, the light-emitting sub-pixel 20 can emit light under the driving of the voltage signal and the second power signal.

As an optional implementation, as shown in FIG. 6, the above light-emitting sub-pixel 20 may include a pixel driving circuit 21 and a light-emitting element L, the first electrode of the light-emitting sub-pixel 20 may be a cathode of the light-emitting element L, and the second electrode of the light-emitting sub-pixel 20 may be an anode of the light-emitting element L. The voltage signal received by the first electrode of the light-emitting sub-pixel 20 may be a negative power signal ELVSS, and the second electrode of the light-emitting sub-pixel 20 receives a driving current. Current magnitude of the driving current may be controlled by a driving transistor in the pixel driving circuit 21.

The anode of the light emitting element L may receive a driving current through the pixel driving circuit 21. The first electrode (e.g., the cathode) of the light-emitting element L may receive the negative power signal ELVSS through the first voltage signal line ELVSS. The pixel driving circuit 21 may be connected between a positive power signal ELVDD and the anode of the light-emitting element L. The driving transistor in the pixel driving circuit 21 may generate a driving current according to a gate-source voltage difference to drive the light-emitting element L to emit light.

It may be understood that FIG. 6 is only based on an example in which the pixel driving circuit 21 is 2T1C. In addition, the above pixel driving circuit 21 may alternatively be a circuit structure such as 3T1C, 4T2C, 5T1C, 7T1C, or 8T1C, which is not limited herein.

In the related art, the first electrode (e.g., the cathode) of the light-emitting element L in the light-emitting sub-pixel 20 covers the entire surface of the display panel. In an optional implementation of the present application, an isolation structure is provided between the first electrodes (e.g., the cathodes) of the light-emitting elements L. The isolation structure can partition the first electrodes (e.g., the cathodes) between adjacent light-emitting elements L for isolation and insulation or connect the first electrodes (e.g., the cathodes) between the adjacent light-emitting elements L for electrical connections.

If the isolation structure between the first electrodes (e.g., the cathodes) of two adjacent light-emitting sub-pixels 20 is made of a conductive material, the first electrodes (e.g., the cathodes) of the two adjacent light-emitting sub-pixels 20 can be electrically connected through the isolation structure. When the first voltage signal line ELVSS is electrically connected to one of the first electrodes (e.g., the cathodes), a same power signal can be provided for the two first electrodes (e.g., the cathodes).

If the isolation structure between the first electrodes (e.g., the cathodes) corresponding to the two adjacent light-emitting sub-pixels 20 can play an insulation effect, the first electrodes (e.g., the cathodes) corresponding to the two adjacent light-emitting sub-pixels 20 can be insulated and isolated. When the first voltage signal line ELVSS is electrically connected to one of the first electrodes (e.g., the cathodes), the other first electrode (e.g., the cathode) may not receive the power signal provided by the voltage signal line.

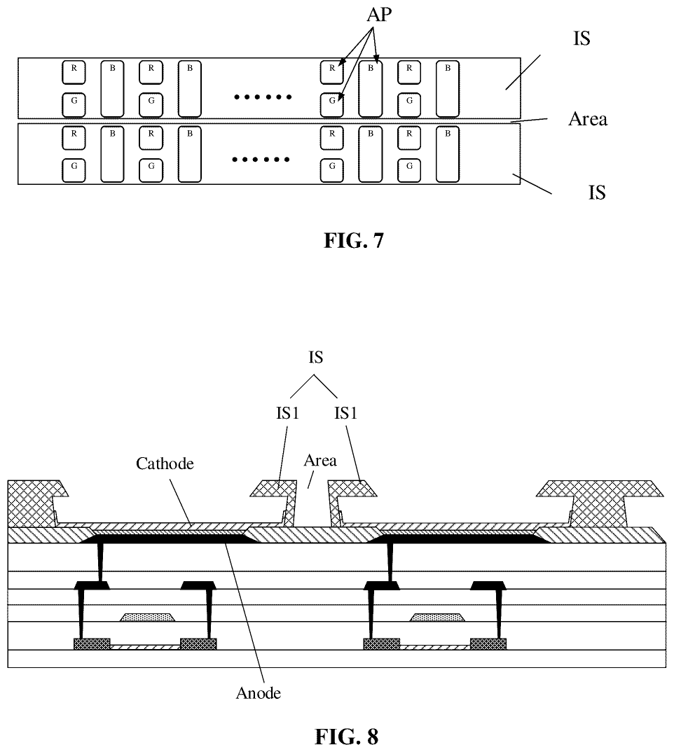

As shown in FIG. 7, taking the first electrodes (e.g., the cathodes) corresponding to two rows of adjacent light-emitting sub-pixels 20 as an example, in this embodiment, each group of light-emitting sub-pixels 20 may include only one row of light-emitting sub-pixels 20, AP denotes a pixel opening region corresponding to each light-emitting sub-pixel 20, IS denotes an isolation structure of the light-emitting sub-pixel, and Area denotes an isolation region in the isolation structure between two rows of light-emitting sub-pixels. It may be understood that the first electrodes corresponding to the light-emitting sub-pixels 20 in a same row have a same potential, and the first electrodes corresponding to the light-emitting sub-pixels 20 in different rows are insulated and isolated, so the potentials may be different.

FIG. 8 is a schematic diagram of a layer structure in which two rows of light-emitting sub-pixels 20 in two adjacent groups are isolated and insulated by using an isolation pillar. Cathodes of two light-emitting sub-pixels 20 are connected to a same isolation pillar IS. A partition groove Area is provided on the isolation pillar IS. An orthographic projection of the partition groove Area on the substrate is located between orthographic projections of two adjacent groups of light-emitting sub-pixels 20 on the substrate. The partition groove Area can partition the isolation pillar IS to form two sub-isolation pillars IS1 to achieve insulation between the two sub-isolation pillars IS1, thereby insulating the cathodes of the two light-emitting sub-pixels 20 from each other.

The first electrodes corresponding to respective rows of light-emitting sub-pixels 20 can be isolated from each other by isolating the first electrodes corresponding to the rows of light-emitting sub-pixels 20 through the above isolation structure. For example, when the first signal module 11 is connected to the first electrodes corresponding to one row of light-emitting sub-pixels 20, through the arrangement of the above isolation structure, the first electrodes of the row of light-emitting sub-pixels 20 can be isolated from the first electrodes of an adjacent row of light-emitting sub-pixels 20, and at the same time, the first electrodes corresponding to the light-emitting sub-pixels 20 in the row are electrically connected to each other.

Similarly, when the first signal module 11 is connected to the first electrodes corresponding to multiple rows of light-emitting sub-pixels 20, through the arrangement of the above isolation structure, the first electrodes of the multiple rows of light-emitting sub-pixels 20 can be electrically connected to each other.

When the first voltage signal line ELVSS is connected to the first electrode corresponding to one or more rows of light-emitting sub-pixels 20 through the first signal module 11, the first voltage signal line ELVSS can provide a same voltage signal for all the light-emitting elements L in the one or more rows of light-emitting sub-pixels 20, while the light-emitting elements in the remaining rows of light-emitting sub-pixels 20 that are not connected to the first signal module 11 L cannot receive voltage signals through the first signal module 11.

It is to be noted that in addition to the above isolation structure, insulation and isolation between the rows of light-emitting sub-pixels 20 may alternatively be achieved in other manners. For example, the first electrodes (for example, the cathodes) of the light-emitting elements L in the light-emitting sub-pixels 20 may not cover the entire surface of the display panel. Instead, the first electrodes of the rows of light-emitting sub-pixels 20 are arranged in sequence, and the first electrodes of the adjacent rows of light-emitting sub-pixels 20 are insulated from each other.

In the light-emitting element L of the light-emitting sub-pixel 20, there is a parasitic capacitor between the anode and the cathode of the light-emitting element L. When the first signal module 11 is turned on, the light-emitting element L emits light under the driving current provided by the pixel driving circuit 21. In this case, the parasitic capacitor can store a certain amount of electric charge. When the first signal module 11 is turned off, due to a characteristic that voltages at two ends of the parasitic capacitor cannot be changed suddenly, a potential of the first electrode corresponding to each light-emitting sub-pixel 20 is still a signal voltage of the voltage signal. However, as electrons stored in the parasitic capacitor continue to be recombined with holes to emit light in the light-emitting element L, the voltages at the two ends of the parasitic capacitor will gradually decrease, so that the potential of the first electrode of the light-emitting element L gradually approaches a potential of the second electrode. In this case, brightness of the light-emitting element L may also gradually decrease. When a potential difference between the second electrode and the first electrode of the light-emitting element L, that is, a voltage difference (Vn3−Vn4) between Node n3 and Node n4, decreases below the turn-on voltage Von of the light-emitting element L, the light-emitting element L will go out. That is, after the first signal module 11 is turned off, the potential of the first electrode corresponding to the light-emitting sub-pixel 20 connected to the first signal module 11 will gradually tend to be the potential of the second electrode, causing the brightness of the light-emitting element L to gradually decrease until the light-emitting element goes out.

When the light-emitting element L of the light-emitting sub-pixel 20 goes out, the light-emitting sub-pixel 20 is in the non-light-emitting stage. In this case, steps such as data voltage writing and initialization may be performed on one or more rows of light-emitting sub-pixels 20 in the non-light-emitting stage, so that the light-emitting sub-pixels 20 can display target brightness corresponding to a data voltage when re-entering the light-emitting stage.

In this embodiment, through the arrangement of the first signal module 11, one or more rows of light-emitting sub-pixels 20 may be connected to the first voltage signal line ELVSS through the first signal module 11. When the first signal module 11 is turned on, the first electrode of the light-emitting sub-pixel 20 can receive the voltage signal provided by the first voltage signal line ELVSS and is in the light-emitting stage. However, when the first signal module 11 is turned off, the first electrode of the light-emitting sub-pixel 20 cannot receive the voltage signal and is in the non-light-emitting stage. By controlling the on and off of the first signal module 11, the light-emitting sub-pixels 20 may be switched between the light-emitting stage and the non-light-emitting stage, thereby achieving independent light-emitting control over each group of light-emitting sub-pixels 20. When a plurality of first signal modules 11 are provided in the display panel, each group of light-emitting sub-pixels 20 can be independently controlled through the plurality of first signal modules 11, thereby realizing group-by-group lighting of the light-emitting sub-pixels 20.

Referring to FIG. 9, in some embodiments, the above first signal module 11 may include a first transistor T1, a first electrode of the first transistor T1 is connected to the first voltage signal line ELVSS, a second electrode of the first transistor T1 is connected to the first electrodes of one group of light-emitting sub-pixels 20, and a gate of the first transistor T1 is connected to the first control signal line EM.

The first control signal line EM may provide a light-emitting signal and a non-light-emitting signal. The first transistor T1 is turned on under the light-emitting signal and turned off under the non-light-emitting signal.

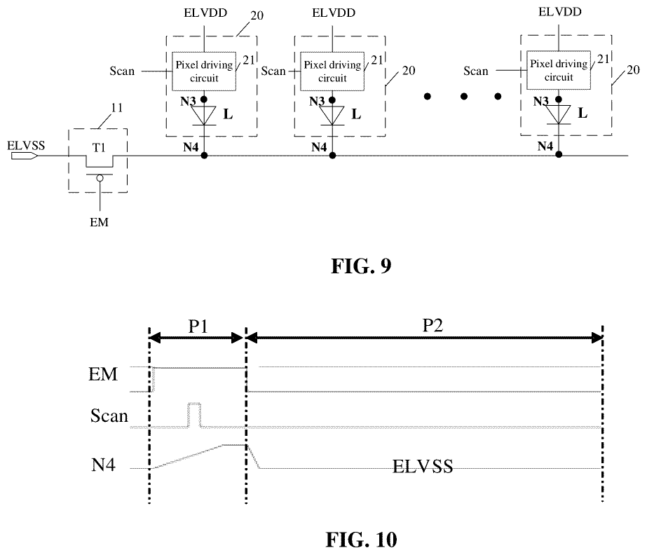

Referring to FIG. 10, a high-level signal of the first control signal line EM is a non-light-emitting signal, and a low-level signal is a light-emitting signal. When the first control signal line EM provides the high-level signal, the first signal module 11 is turned off. In this case, the potential of Node n4, that is, the potential of the first electrode, will gradually increase until the voltage difference between the second electrode and the first electrode of the light-emitting sub-pixel 20 is lower than the turn-on voltage. In a time interval of the high-level signal provided by the first control signal line EM, the scan signal may provide a high-level pulse as an enable active signal, so that a data writing transistor in the pixel driving circuit 21 is turned on. In this case, a data signal Vdata can be written into the light-emitting sub-pixel 20 to realize data signal writing in the non-light-emitting stage.

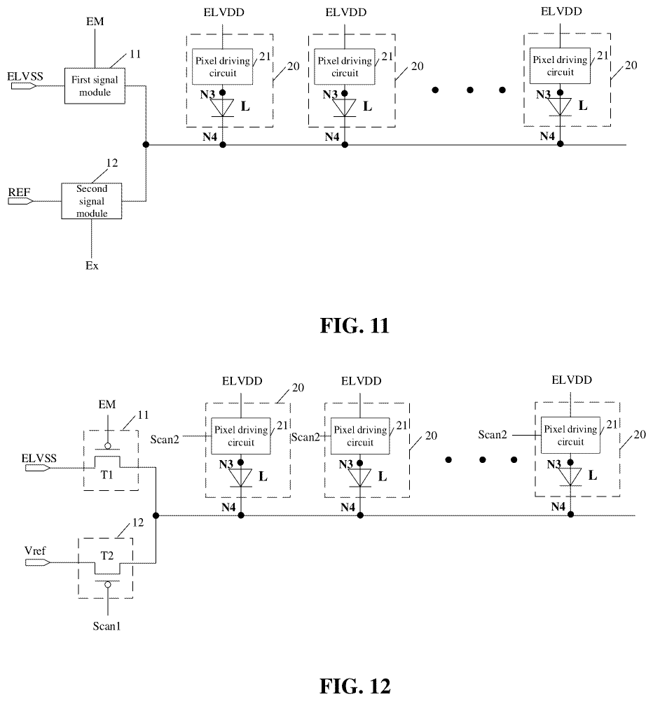

Referring to FIG. 11, in some embodiments, the above power selection circuit may further include a second signal module 12, and the voltage signal line may further include a second voltage signal line. For example, the second voltage signal line in FIG. 11 is REF, but is not limited thereto.

The second signal module 12 includes a first terminal, a second terminal, and a control terminal. The first terminal of the second signal module 12 is connected to the second voltage signal line, the second terminal of the second signal module 12 is connected to the second terminal of the first signal module 11, and the control terminal of the second signal module 12 is connected to a second control signal line. The second control signal line in FIG. 11 is Ex.

In the non-light-emitting stage, a voltage signal transmitted in the second voltage signal line is greater than the difference between the second electrode voltage of the light-emitting sub-pixel 20 and the turn-on voltage of the light-emitting sub-pixel 20. That is, when the second voltage signal line provides a voltage signal for the first electrode of the light-emitting sub-pixel 20, the voltage difference between the second electrode and the first electrode of the light-emitting sub-pixel 20 is less than the turn-on voltage of the light-emitting sub-pixel 20. In this case, the light-emitting sub-pixel 20 does not emit light.

When the second signal module 12 is turned on, the first electrode corresponding to the light-emitting sub-pixel 20 may receive the voltage signal provided by the second voltage signal line through the second signal module 12, and the potential of the first electrode corresponding to the light-emitting sub-pixel 20 becomes a signal voltage of the second voltage signal line. In this case, the voltage difference between the second electrode and the first electrode corresponding to the light-emitting sub-pixel 20 should be lower than the turn-on voltage of the light-emitting sub-pixel 20. That is, when the second signal module 12 is turned on, the second voltage signal line can adjust the potential of the first electrode corresponding to the light-emitting sub-pixel 20, so that the light-emitting element L in the light-emitting sub-pixel 20 goes out because the voltage difference at the two ends is lower than the turn-on voltage.

For example, the first electrode is a cathode. In order to make the voltages at two ends of the light-emitting element L lower than the turn-on voltage, the voltage signal should raise the potential of the first electrode. That is, the signal voltage of the voltage signal should be higher than the voltage of the first electrode. However, when the first signal module 11 is turned on, the voltage signal cannot raise the potential of the first electrode. Therefore, when the second signal module 12 is turned on, in order to effectively adjust the potential of the first electrode, the first signal module 11 is in an off state.

Referring to FIG. 12, the above first signal module 11 may include a first transistor T1, a first electrode of the first transistor T1 is connected to the first voltage signal line ELVSS, a second electrode of the first transistor T1 is connected to the first electrodes of one group of light-emitting sub-pixels 20, and a gate of the first transistor T1 is connected to the first control signal line EM.

The second signal module 12 may include a second transistor T2, a first terminal of the second transistor T2 is connected to an initialization signal line, a first electrode of the second transistor T2 is connected to the second voltage signal line, a second electrode of the second transistor T2 is connected to the second electrode of the first transistor T1, and a gate of the second transistor T2 is connected to the second control signal line.

In some embodiments, a type of the first transistor T1 may be opposite to a type of the second transistor T2, and a signal in the first control signal line EM and a signal in the second control signal line are a same signal.

In some embodiments, the first control signal line EM and the second control signal line may be a same signal line. That is, the same signal line is connected to the gate of the first transistor T1 and the gate of the second transistor T2 respectively.

It may be understood that under a same control signal, on states of different types of transistors are opposite. That is, when one transistor is on, the other transistor is off.

As an optional implementation, one of the first transistor T1 and the second transistor T2 may be an N-type transistor, and the other may be a P-type transistor. When the first transistor T1 and the second transistor T2 are N-type and P-type respectively, the two transistors can be in opposite states through the same control signal. That is, only one of the first transistor T1 and the second transistor T2 is in an on state. When the first transistor T1 is turned on, the light-emitting sub-pixel 20 is in the light-emitting stage. When the second transistor T2 is turned on, the light-emitting sub-pixel 20 is in the non-light-emitting stage.

In some embodiments, the type of the first transistor T1 may be the same as the type of the second transistor T2, and the signal in the first control signal line EM and the signal in the second control signal line are opposite signals.

“The signal in the first control signal line EM and the signal in the second control signal line are opposite signals” means that when the first control signal line EM provides an on signal to drive the first transistor T1 to be turned on, the second control signal line provides an off signal to drive the second transistor T2 to be turned off; and when the second control signal line provides an on signal to drive the second transistor T2 to be turned on, the first control signal line EM provides an off signal to drive the first transistor T1 to be turned off.

In some embodiments, the signal in the first control signal line EM and the signal in the second control signal line are both step-by-step shift signals.

Taking the first control signal line EM as an example, when each first control signal line EM provides a step-by-step shift active signal to each first signal module 11, each first signal module 11 will sequentially disconnect the first electrode of the corresponding light-emitting sub-pixel from the first voltage signal line one by one.

Similarly, when each second control signal line provides a step-by-step shift active signal to each second signal module 12, each second signal module 12 will sequentially disconnect the first electrode of the corresponding light-emitting sub-pixel from the second voltage signal line one by one. A certain group of light-emitting sub-pixels 20 is in the light-emitting stage when connected to the first voltage signal line, and the light-emitting sub-pixels 20 can emit light when receiving the driving current. The group of light-emitting sub-pixels is in the non-light-emitting stage when disconnected from the first voltage signal line and connected to the second voltage signal line to reduce a voltage (Vn3−Vn4) between the second electrode and the first electrode of the light-emitting element L to a value lower than the turn-on voltage Von of the light-emitting element L, the light-emitting sub-pixels 20 do not emit light.

In some embodiments, a signal duty cycle in the first control signal line EM and a signal duty cycle in the second control signal line are both adjustable.

When the first control signal line EM provides an on signal, the first transistor T1 is in an on state. In this case, the light-emitting sub-pixel 20 connected to the first transistor T1 can emit light. However, when the first control signal line EM provides an off signal, the first transistor T1 is in an off state. In this case, the light-emitting sub-pixel 20 connected to the first transistor T1 does not emit light. By adjusting the duty cycle of the first control signal line EM, an actual light-emitting time of the light-emitting sub-pixel 20 in the light-emitting stage of a single light-emitting frame can also be adjusted, thereby adjusting light-emitting brightness in a pulse width modulation (PWM) driving manner.

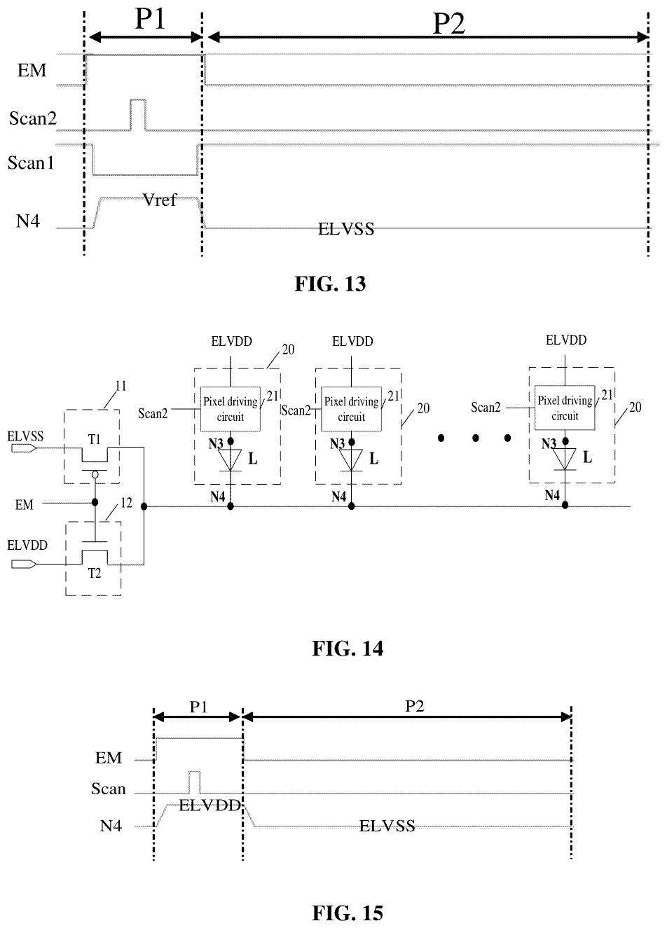

Referring to FIG. 13, in some embodiments, the above second voltage signal line may be an initialization signal line, and the second control signal line may be a row driving signal line.

For example, a single first signal module 11 is in a single light-emitting frame. The first control signal line EM may provide a non-light-emitting signal in a first time interval, and the first signal module 11 receives the non-light-emitting signal and is turned off in the first time interval. In this case, the light-emitting sub-pixel 20 connected to the first signal module 11 is in the non-light-emitting stage.

The row driving signal line may provide an initialization control signal in a second time interval, and the second signal module 12 may receive the initialization control signal and be turned on in the second time interval. When the second signal module 12 is turned on, an initialization signal provided by the initialization signal line can increase the potential of the first electrode, so that the voltages at two ends of the light-emitting element L faster drop below the turn-on voltage and the light-emitting sub-pixel 20 rapidly goes out. In this case, to enable the potential of the first electrode to rise, there is a need to prevent a connection between the first voltage signal line ELVSS and the first electrode. That is, in the second time interval during which the second signal module 12 is turned on, the first signal module 11 should always remain in the off state. Therefore, the first time interval during which the first control signal line EM provides the non-light-emitting signal may cover the second time interval during which the initialization control signal is provided by the row driving signal line, so that when the second signal module 12 is turned on, the first signal module 11 is in a stable off state.

Referring to FIG. 14, a high-level signal of the first control signal line EM is a non-light-emitting signal, and a low-level signal is a light-emitting signal. When the first control signal line EM provides a high-level signal, the first signal module 11 is turned off. In the initialization control signal provided by the row driving signal line, the low level is an active signal. When the row driving signal line is a low-level signal, the second signal module 12 is turned on. In this case, the potential of Node n4, that is, the potential of the first electrode, will quickly rise to the initialization voltage Vref, so that the voltage difference between the second electrode and the first electrode of the light-emitting sub-pixel 20 is lower than the turn-on voltage.

In a time interval during which the first signal module 11 is turned off and the second signal module 12 is turned on, a scan signal Scan2 may provide a high-level pulse as an enable active signal, so that the data writing transistor in the pixel driving circuit 21 is turned on. In this case, the data signal Vdata can be written into the light-emitting sub-pixel 20 to realize data signal writing in the non-light-emitting stage.

The first transistor T1 and the second transistor T2 may be configured as P-type transistors. In the related art, the transistor provided in the display panel is generally a thin film transistor (TFT). The TFT includes an N-type TFT and a P-type TFT. The P-type TFT is generally a low temperature poly-silicon (LTPS) TFT or the like. The N-type TFT is generally an oxide transistor such as an indium gallium zinc oxide (IGZO) TFT. Since the LTPS TFT is featured with a smaller area and higher mobility than the IGZO TFT, connecting the P-type transistor between the first electrode and the signal line can improve charging efficiency of the first electrode and reduce an overall area of the power selection circuit.

In some embodiments, the above second voltage signal line may be a positive power signal line.

The positive power signal line may provide a positive power signal ELVDD for the light-emitting sub-pixel 20. When the second signal module 12 is turned on, the first electrode corresponding to the light-emitting sub-pixel 20 is connected to the second voltage signal line, and the voltage difference between the second electrode corresponding to the light-emitting sub-pixel 20 and the first electrode is lower than the turn-on voltage. In this case, the light-emitting element L is in an off state.

Since the positive power signal line is a necessary power supply signal line for the light-emitting sub-pixel 20 to emit light, directly using the positive power signal line as the second voltage signal line can also make a potential difference between the second electrode and the first electrode of the light-emitting sub-pixel 20 lower than the turn-on voltage, so that the light-emitting sub-pixel 20 is in the non-light-emitting stage. Compared with the use of a second voltage signal line that provides other voltage signals, directly reusing the second voltage signal line as the second voltage signal line can reduce a number of signal traces in the display panel and reduce difficulty of wiring.

Referring to FIG. 15, a high-level signal of the first control signal line EM is a non-light-emitting signal, and a low-level signal is a light-emitting signal. When the first control signal line EM provides a high-level signal, the first signal module 11 is turned off and the second signal module 12 is turned on. In this case, the potential of Node n4, that is, the potential of the first electrode, will quickly rise to the second power signal ELVDD, so that the voltage difference between the second electrode and the first electrode of the light-emitting sub-pixel 20 is lower than the turn-on voltage.

In the time interval during which the first signal module 11 is turned off and the second signal module 12 is turned on, the scan signal Scan may provide a high-level pulse as an enable active signal, so that the data writing transistor in the pixel driving circuit 21 is turned on. In this case, the data signal Vdata can be written into the light-emitting sub-pixel 20 to realize data signal writing in the non-light-emitting stage.

An embodiment of the present application further provides a display panel. The display panel may include a plurality of groups of light-emitting sub-pixels 20 arranged in an array and a power selection module 1. The power selection module 1 may be the power selection module 1 in the above embodiments.

In the plurality of groups of light-emitting sub-pixels 20 arranged in an array, for example, n rows of the light-emitting sub-pixels are provided. Each group of light-emitting sub-pixels 20 may include x rows of consecutive light-emitting sub-pixels 20 or x rows of light-emitting sub-pixel units, and one light-emitting sub-pixel unit includes at least two different light-emitting sub-pixels 20, where x<n, and x is a positive integer.

It is to be noted that in the two groups of light-emitting sub-pixels as shown in FIG. 7, one group of light-emitting sub-pixels may alternatively be formed by light-emitting sub-pixel units and light-emitting sub-pixels 20 arranged at intervals.

When x=1, a group number of the plurality of groups of light-emitting sub-pixels 20 is a row number of the light-emitting sub-pixels 20 in the display panel. When x>1, the group number of the plurality of groups of light-emitting sub-pixels 20 is the row number of the light-emitting sub-pixels 20 in the display panel divided by a row number x of the light-emitting sub-pixels 20 in each group, that is, (n/x).

In a same group of light-emitting sub-pixels 20, the first electrodes corresponding to any two light-emitting sub-pixels 20 are electrically connected. That is, in the same group of light-emitting sub-pixels 20, potentials of the first electrodes corresponding to all the light-emitting sub-pixels 20 are the same.

In different groups of light-emitting sub-pixels 20, the first electrodes corresponding to any two light-emitting sub-pixels 20 are isolated and insulated from each other. That is, the first electrodes corresponding to two light-emitting sub-pixels 20 in the different groups of light-emitting sub-pixels 20 may be the same or different.

One power selection circuit is connected to the first electrodes of one group of light-emitting sub-pixels 20. When the display panel includes a plurality of groups of light-emitting sub-pixels 20, a plurality of power selection modules 1 may be provided to be connected to the plurality of groups of light-emitting sub-pixels 20 in one-to-one correspondence. A first terminal of each power selection module 1 is connected to the voltage signal line, a second terminal of each power selection module 1 is connected to the first electrodes corresponding to one group of light-emitting sub-pixels 20, and a control terminal of each power selection module 1 is connected to the first control signal line EM.

In this embodiment, by arranging a plurality of power selection modules 1 to be respectively connected to the first electrodes of each group of light-emitting sub-pixels 20, light-emitting states of each group of light-emitting sub-pixels 20 can be controlled through the power selection modules 1. By sequentially controlling each power selection module 1 to be turned off, the light-emitting sub-pixels 20 of each group of light-emitting sub-pixels 20 can sequentially enter the non-light-emitting stage. By sequentially controlling each power selection module 1 to be turned on, the light-emitting sub-pixels 20 of each group of light-emitting sub-pixels 20 can sequentially enter the light-emitting stage. Since the light-emitting stage and the non-light-emitting stage of each group of light-emitting sub-pixels 20 can be independently adjusted, group-by-group lighting of each group of light-emitting sub-pixels 20 can be achieved.

In some embodiments, the first electrodes of the light-emitting sub-pixels 20 in adjacent rows of light-emitting sub-pixels 20 or adjacent rows of light-emitting sub-pixel units in a same group are electrically connected through an isolation pillar.

When one group of light-emitting sub-pixels 20 includes at least two rows of light-emitting sub-pixels 20, the first electrodes of the light-emitting sub-pixels 20 in adjacent rows can be electrically connected through an isolation pillar. When the first electrodes of any row of light-emitting sub-pixels 20 are connected to the voltage signal line through the power selection circuit, an adjacent row of light-emitting sub-pixels 20 electrically connected to the row of light-emitting sub-pixels 20 through the isolation pillar is also equivalent to being connected to the voltage signal line.

As shown in FIG. 8, in some embodiments, the isolation pillar IS between the light-emitting sub-pixels 20 in the light-emitting sub-pixels 20 in different groups and adjacent rows or the light-emitting sub-pixel units in different groups and adjacent rows is provided with a partition groove Area. The partition groove Area can divide the isolation pillar IS into two sub-isolation pillars IS1, and the two sub-isolation pillars IS1 are respectively a first sub-isolation pillar and a second sub-isolation pillar. The first sub-isolation pillar and the second sub-isolation pillar are insulated.

In two adjacent pixel rows in different groups, the light-emitting sub-pixels 20 in one row of light-emitting sub-pixels 20 or one row of light-emitting sub-pixel units are electrically connected to the first sub-isolation pillar, and the light-emitting sub-pixels 20 in the other row of light-emitting sub-pixels 20 or the other row of light-emitting sub-pixel units are electrically connected to the second sub-isolation pillar. That is, first electrodes of the two adjacent pixel rows in different groups are insulated from each other.

In some embodiments, the above isolation pillar may include a metal isolation pillar.

In some embodiments, in a direction perpendicular to an extension direction of a single group of the light-emitting sub-pixels 20, a cross-sectional shape of a conductive part of the isolation pillar includes, but is not limited to, a T shape or an inverted trapezoid.

As an optional implementation, the power selection circuit may be connected to the isolation pillar. Since the isolation pillar can connect two adjacent rows of light-emitting sub-pixels 20 in a same group of light-emitting sub-pixels 20, the power selection circuit can transmit the voltage signal of the voltage signal line to the isolation pillar when turned on. The isolation pillar can provide voltage signals for the first electrodes of two adjacent rows of light-emitting sub-pixels 20. At the same time, other rows of light-emitting sub-pixels 20 in a same group that are directly or indirectly electrically connected to the two rows of light-emitting sub-pixels 20 can also receive voltage signals.

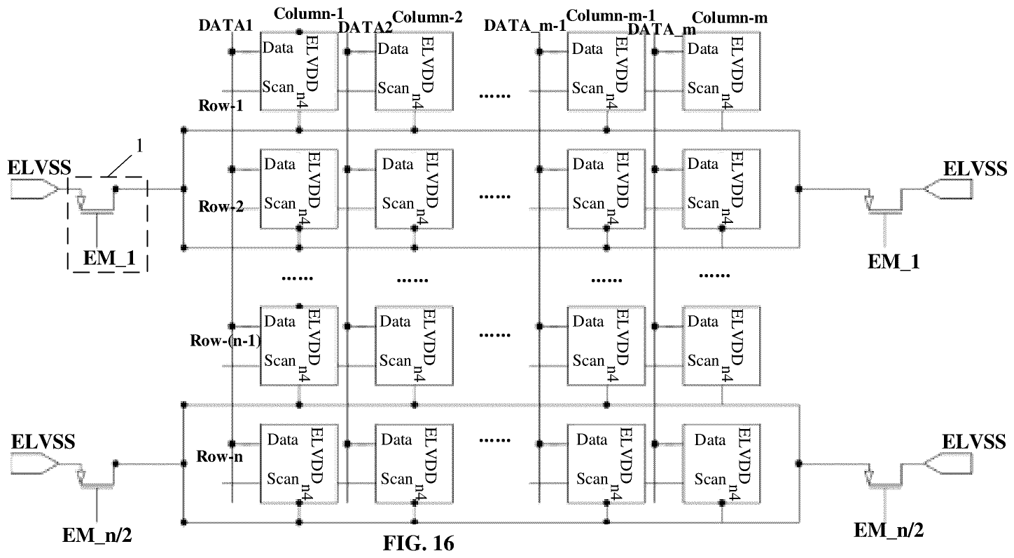

Referring to FIG. 16, FIG. 16 is based on an example in which a single group of light-emitting sub-pixels 20 includes x rows of consecutive light-emitting sub-pixels 20. In the light-emitting sub-pixels 20 in n rows and m columns, n/2 power selection modules 1 are provided correspondingly. As shown in FIG. 12, the n/2 power selection modules 1 are respectively connected to first control signal lines EM_1, EM_2, . . . , and EM_n/2. By outputting light-emitting control signals row by row through the plurality of first control signal lines EM, the n/2 power selection modules 1 can be turned on one by one.

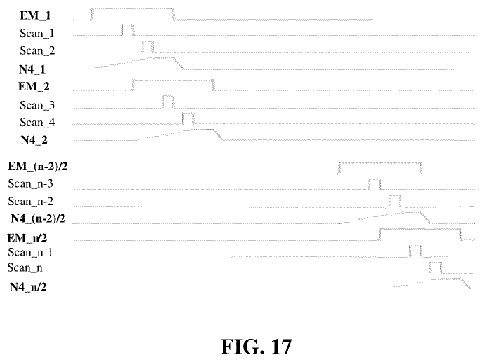

Referring to FIG. 17, when a single group of light-emitting sub-pixels 20 includes x rows of consecutive light-emitting sub-pixels 20, taking the first control signal line EM_1 as an example, when the first control signal line EM_1 provides a high-level signal, the light-emitting sub-pixels 20 in Row 1 and Row 2 are both in a non-light-emitting state. In this case, data signals can be written to the light-emitting sub-pixels 20 in Row 1 and Row 2 successively by sequentially providing scan signals Scan_1 and Scan_2. Similarly, when the first control signal line EM_n/2 provides a high-level signal, the light-emitting sub-pixels 20 in Row n-1 and Row n are both in the non-light-emitting state. In this case, data signals can be written to the light-emitting sub-pixels 20 in Row n-1 and Row n successively by sequentially providing the scan signals Scan_1 and Scan_2.

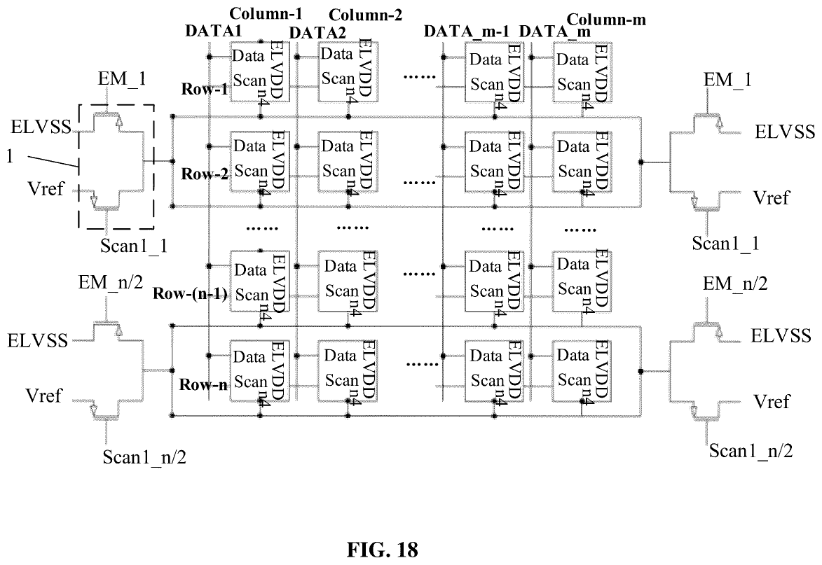

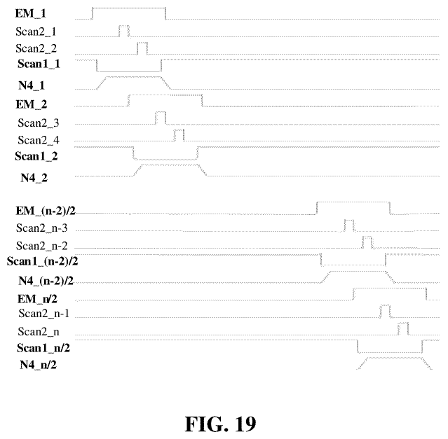

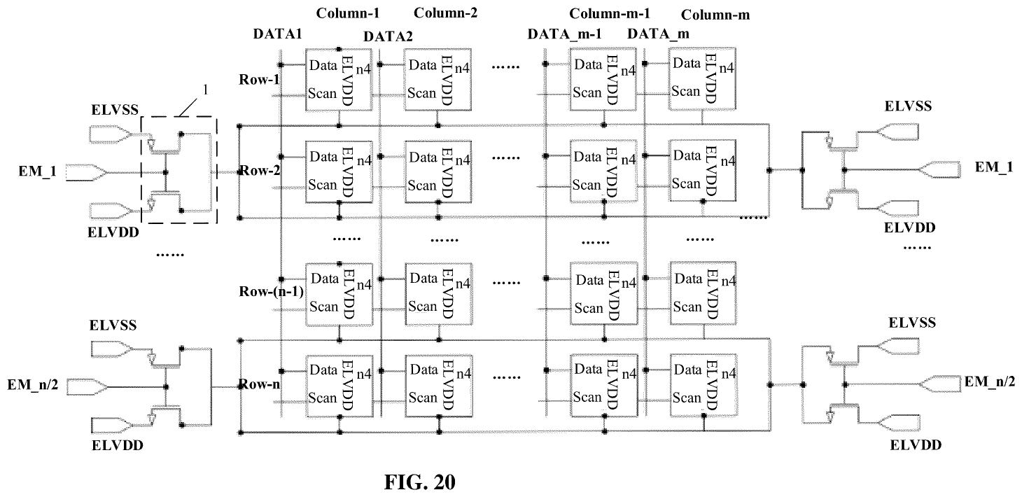

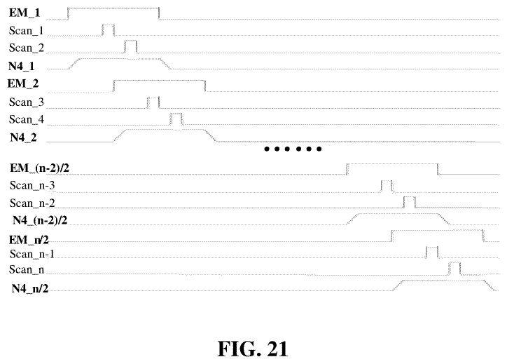

Similarly, FIG. 18 and FIG. 20 are respectively schematic diagrams of a circuit structure of the display panel of the power selection module 1 in two other embodiments. FIG. 18 and FIG. 20 are also both based on an example in which a single group of light-emitting sub-pixels 20 includes x rows of consecutive light-emitting sub-pixels 20. FIG. 19 is a signal timing diagram corresponding to circuit architecture in FIG. 18, and FIG. 21 is a signal timing diagram corresponding to circuit architecture in FIG. 20.

In some embodiments, the above display panel may further include a plurality of scan signal lines, and each scan signal line is electrically connected to a corresponding row of light-emitting sub-pixels 20. The plurality of scan signal lines can output enable active levels of scan signals row by row, so that each row of light-emitting sub-pixels 20 can write data voltage signals row by row.

When each group of light-emitting sub-pixels 20 includes one row of light-emitting sub-pixels 20, each row of light-emitting sub-pixels 20 is connected to one power selection module 1 and one scan signal line. When the power selection module 1 corresponding to the row of light-emitting sub-pixels 20 is in an off state, the row of light-emitting sub-pixels 20 is in the non-light-emitting stage. In this case, the scan signal line can provide an enable active level for the row of light-emitting sub-pixels 20, so that the data writing transistor in the pixel driving circuit 21 is turned on, and the data voltage can be written into the light-emitting sub-pixels 20 through the data writing transistor.

When the power selection module 1 is in an on state, the row of light-emitting sub-pixels 20 is in the light-emitting stage. The data voltage signal written in the non-light-emitting stage enables the driving transistor in the pixel driving circuit 21 to generate a corresponding driving current, so that the light-emitting sub-pixels 20 display corresponding target brightness.

When each group of light-emitting sub-pixels 20 includes at least two rows of light-emitting sub-pixels 20, a number of corresponding scan signal lines in a single group of light-emitting sub-pixels 20 is a number of rows of the light-emitting sub-pixels 20. For example, when each group of light-emitting sub-pixels 20 includes three rows of light-emitting sub-pixels 20, there are three corresponding scan signal lines in the single group of light-emitting sub-pixels 20.

It may be understood that a plurality of light-emitting sub-pixel rows in a same group of light-emitting sub-pixels 20 are featured with state synchronization. For example, a single group of light-emitting sub-pixels 20 includes three rows of light-emitting sub-pixels 20. When the power selection module 1 is turned on, the three light-emitting sub-pixel rows are all in the light-emitting stage. When the power selection module 1 is turned off, the three light-emitting sub-pixel rows are all in the non-light-emitting stage.

In a single light-emitting frame, the first control signal line EM may provide a non-light-emitting signal in the first time interval. In this case, the first signal module 11 is in an off state in the first time interval, and the three light-emitting sub-pixel rows are all in the non-light-emitting stage. In the non-light-emitting stage, three scan signal lines corresponding to the group of light-emitting sub-pixels 20 can sequentially output enable active levels of the three scan signals row by row, so that the three rows of light-emitting sub-pixels can complete the writing of data signals row by row.

In some embodiments, in a single image frame, a duration of the first time interval of the first signal module 11 is t1, and a duration of a time interval of the enable active level of the scan signal is t2.

When a single group of light-emitting sub-pixels 20 includes x rows of light-emitting sub-pixels 20, to enable the first signal module 11 to complete row-by-row data signal writing of the x rows of light-emitting sub-pixels 20 when in the off state, the following should be satisfied:

t1≥x*t2;
that is, a duration during which the x rows of light-emitting sub-pixels 20 sequentially complete data signal writing x times should be in the off state of the first signal module 11. That is, an off time of the first signal module 11 should include at least enable active levels of x scan signals.

In some embodiments, the above display panel may include a display region and a non-display region, the light-emitting sub-pixels 20 are located in the display region, and the power selection circuit is located in the non-display region.

The power selection module 1 is arranged in the non-display region and may be connected to the first electrode corresponding to the light-emitting sub-pixel 20 in a boundary region between the display region and the non-display region through signal wiring. The display region includes only the light-emitting sub-pixel 20. On the basis of realizing a row-by-row lighting function of the light-emitting sub-pixels, a number of transistors of the pixel driving circuit 21 in the light-emitting sub-pixels 20 can be effectively reduced, thereby reducing an area of a single light-emitting sub-pixel 20 and improving PPI of the display panel. The power selection module 1 is arranged in the non-display region which can also prevent occupation of the area of the display region and improve the PPI of the display panel.

In some embodiments, the non-display region may be located on at least one side of the display region. The power selection circuit in the non-display region may be connected to the first electrode corresponding to the light-emitting sub-pixel 20 in the boundary region between the display region and the non-display region through signal traces.

In some embodiments, the non-display region is located on two opposite sides of the display region, that is, the non-display region may include a first non-display region and a second non-display region. The first non-display region is located on one side of the display region along a first direction, and the second non-display region is located on the other side of the display region along the first direction. Both the first non-display region and the second non-display region include the power selection circuit.

For one group of the plurality of groups of light-emitting sub-pixels 20, the group of light-emitting sub-pixels 20 may be connected to the power selection circuit in the first non-display region, or may be connected to the power selection circuit in the second non-display region.

In some embodiments, the first electrodes of the light-emitting sub-pixels 20 in a same row of the light-emitting sub-pixels 20 or a same row of the light-emitting sub-pixel units are respectively connected to the power selection circuits in the plurality of non-display regions.

A certain group of light-emitting sub-pixels 20 may be connected to a plurality of power selection circuits. The plurality of power selection circuits may be controlled through a same control signal. Compared with the manner of connecting a single power selection module 1 to one group of light-emitting sub-pixels 20, through a plurality of power selection modules 1 and one group of light-emitting sub-pixels 20, a number of light-emitting sub-pixels 20 required to be driven by the single power selection module 1 can be effectively reduced, improving a driving capability of the power selection module 1.

In some embodiments, the first electrodes of the light-emitting sub-pixels 20 in a same row of light-emitting sub-pixels 20 or a same row of light-emitting sub-pixel units are connected to two power selection circuits, and in the two power selection circuits connected to the first electrodes of the light-emitting sub-pixels 20 in the same row of light-emitting sub-pixels 20 or the same row of light-emitting sub-pixel units, one of the power selection circuits is located in the non-display region on one side of the display region, and the other of the power selection circuits is located in the non-display region on the opposite side of the display region.

In the two power selection modules 1 connected to the same row of light-emitting sub-pixels 20, one is connected to the first electrodes corresponding to the light-emitting sub-pixels 20 through signal traces from the first non-display region, and the other is connected to the first electrodes corresponding to the light-emitting sub-pixels 20 through signal traces from the second non-display region. The same row of light-emitting sub-pixels 20 may be connected to the two power selection modules 1 on two sides of the display region respectively.

Compared with the manner of connecting a single power selection module 1 to one group of light-emitting sub-pixels 20, through the arrangement of the two power selection modules 1 on the two sides of the display region, a number of light-emitting sub-pixels 20 required to be driven by the single power selection module 1 can be effectively reduced, improving a driving capability of the power selection module 1. Moreover, the two power selection modules 1 are arranged on the two sides of the display region respectively, which can also prevent uneven brightness between farther light-emitting sub-pixels 20 and closer light-emitting sub-pixels 20 in a same row under a single power module, thereby improving brightness uniformity of the display panel.

It is to be noted that the plurality of power selection modules 1 can be arranged in such a manner that all the power selection modules 1 are arranged in the first non-display region, or all the power selection modules 1 are arranged in the second non-display region, or one part of the power selection modules 1 are arranged in the first non-display region and the other part of the power selection modules 1 are arranged in the second non-display region.

In some embodiments, two power selection modules 1 corresponding to any two adjacent groups of light-emitting sub-pixels 20 are respectively located in the first non-display region and the second non-display region. That is, the plurality of power selection modules 1 are arranged alternately in the first non-display region and the second non-display region.

The plurality of power selection modules 1 are arranged alternately in the first non-display region and the second non-display region respectively, which can prevent inclusion of excessive power selection modules 1 in one of the first non-display region and the second non-display region, prevent an excessively large frame region, and achieve an effect of a narrow frame.

In some embodiments, the above display panel may further include a plurality of shift register units.

The plurality of shift register units are arranged in the non-display region, and each shift register unit is connected to the corresponding first control signal line EM. That is, the plurality of shift register units are configured to generate light-emitting control signals row by row. The first control signal line EM may extend in the non-display region and be connected to the power selection module 1.

The shift register unit and the first control signal line EM are both located in the non-display region, and a length of the signal traces can be greatly reduced, thereby preventing an influence of impedance on the signal traces on the light-emitting control signal and also reducing a number of the signal traces in the display region.

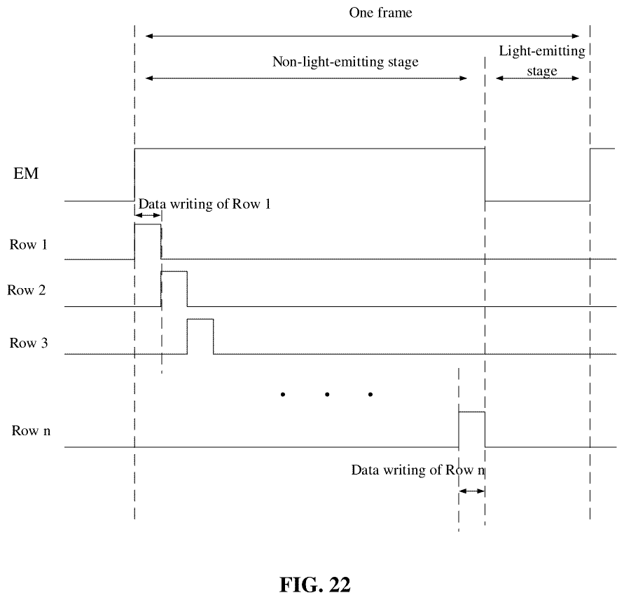

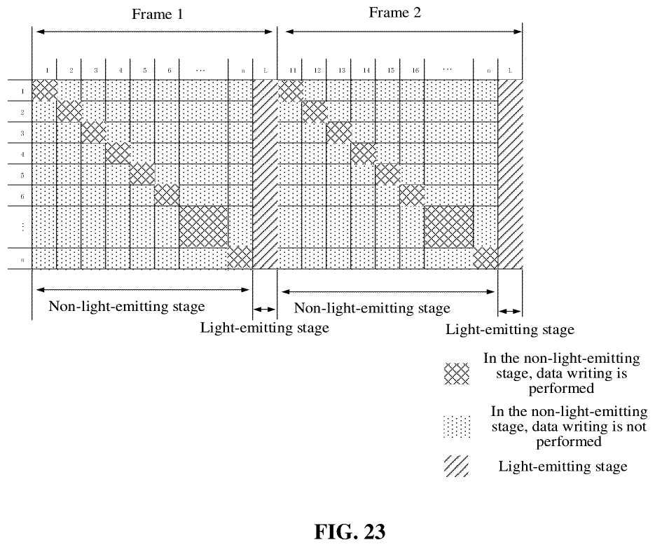

FIG. 22 to FIG. 27 are respectively signal timing diagrams of a single light-emitting frame in three driving manners and schematic diagrams of light-emitting states of respective rows of light-emitting sub-pixels 20. FIG. 22 is a signal timing diagram illustrating that row-by-row or group-by-group lighting of light-emitting sub-pixels 20 cannot be realized caused by a decrease in a number of transistors in the pixel driving circuit 21 in the related art. FIG. 23 is a schematic diagram of light-emitting states of respective rows of light-emitting sub-pixels 20 under the signal timing diagram in FIG. 22. In FIG. 23, serial numbers of respective stages in a single light-emitting frame are in a horizontal direction, and row numbers of different rows of light-emitting sub-pixels 20 are in a vertical direction. That is, Frame 1 includes n data writing stages and one light-emitting stage L. In a first data writing stage, the light-emitting sub-pixels in Row 1 perform data writing, and in an n^{th} data writing stage, the light-emitting sub-pixels in Row n perform data writing. Since all the light-emitting sub-pixels 20 are required to enter the non-light-emitting stage synchronously and the data voltages Vdata are required to be written row by row in the non-light-emitting stage, a duration of the non-light-emitting stage is at least a sum of the n data writing stages. As a result, the time of the light-emitting stage will be greatly reduced. In this case, the time during which all the light-emitting sub-pixels 20 do not emit light in a single light-emitting frame is greatly increased, and at any moment, a probability that all pixels are turned off is greatly increased, resulting in a more serious visual flicker phenomenon.

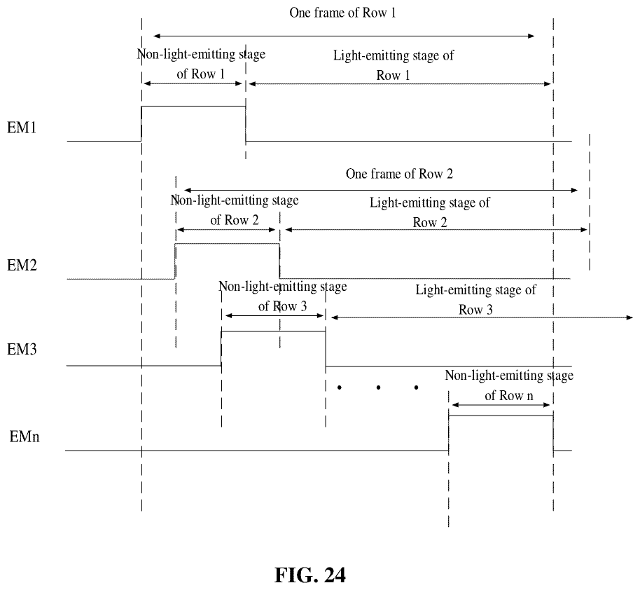

FIG. 24 is a signal timing diagram of different rows of light-emitting sub-pixels 20 in a driving manner adopted in an embodiment of the present application. As shown in FIG. 24, for example, each group of light-emitting sub-pixels 20 includes one row, and the non-light-emitting stages of different groups of light-emitting sub-pixels 20 can be staggered from each other, so that at any moment, only part of the light-emitting sub-pixels 20 do not emit light, which can effectively ameliorate the flicker phenomenon.

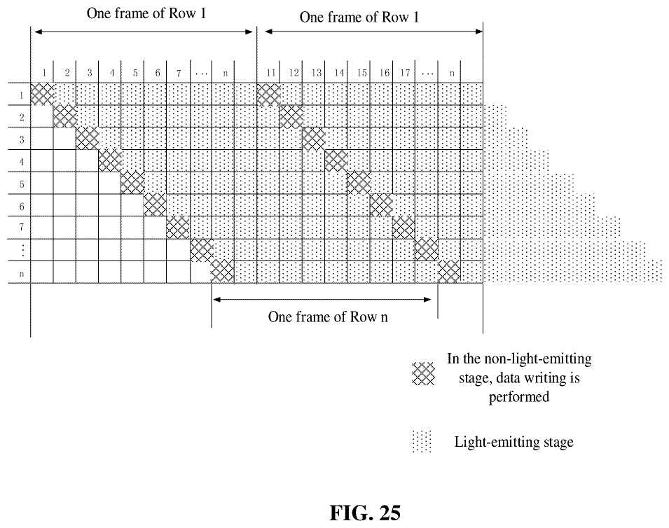

FIG. 25 is a schematic diagram of light-emitting states of respective rows of light-emitting sub-pixels 20 under signal timing control in FIG. 24. It may be understood that the light-emitting sub-pixels in Row 1 perform data writing in a first stage, the light-emitting sub-pixels in Row 2 perform data writing in a second stage, and the light-emitting sub-pixels in Row n perform data writing in an nth stage. Each row of light-emitting sub-pixels 20 can perform data writing independently, thereby greatly increasing a duration ratio of the light-emitting stage to a single light-emitting frame.

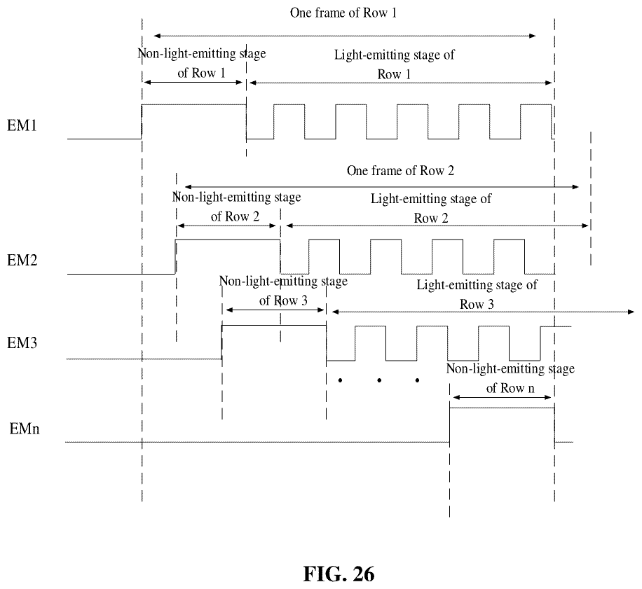

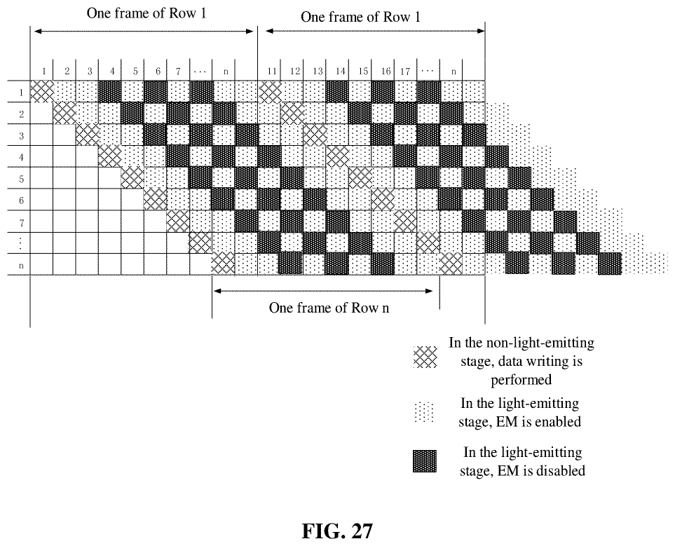

In an optional implementation, as shown in FIG. 26, when the shift register unit provides an EM signal for each row of light-emitting sub-pixels 20, the shift register unit can also adjust a duty cycle of the light-emitting control signal. FIG. 27 is a schematic diagram of light-emitting states of respective rows of light-emitting sub-pixels 20 under signal timing control in FIG. 26. As shown in FIG. 27, in the light-emitting stage, by controlling a duty cycle of the EM signal, in the light-emitting stage, when the EM signal is a non-enable signal, the light-emitting sub-pixel is in a non-light-emitting state. By adjusting the duty cycle of the light-emitting control signal, a total duration of actual light emitting of the light-emitting sub-pixel 20 in the light-emitting stage of a single light-emitting frame can be adjusted and controlled to realize a PWM dimming function.

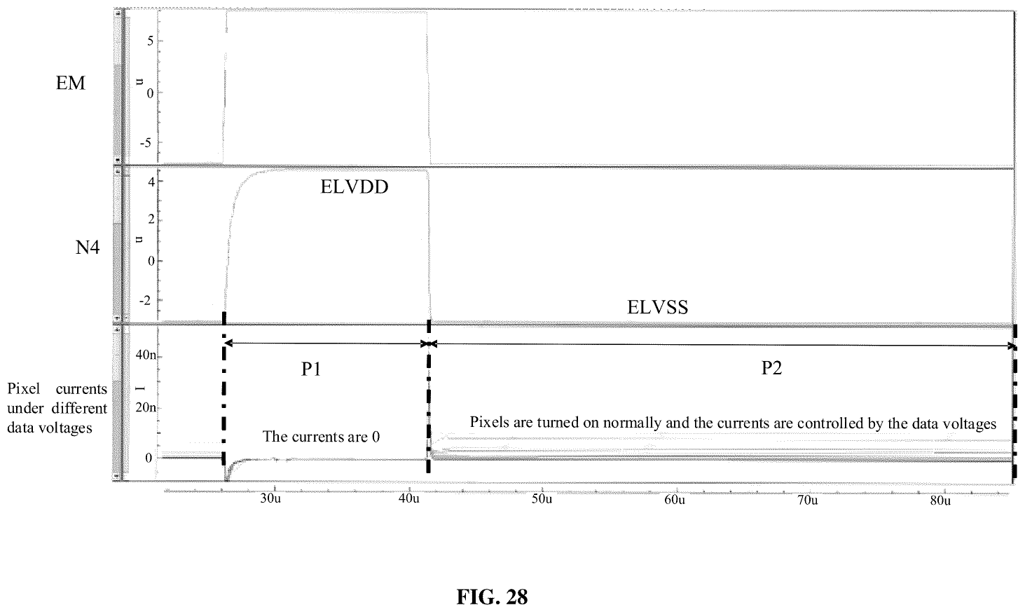

As an example, FIG. 28 is a schematic diagram of voltage and current waveforms in the driving light emitting manner in the above embodiments. For example, the voltage signal in the voltage signal line is ELVDD. When the EM signal jumps from a low level to a high level, the voltage of Node n4 gradually increases to ELVDD. In this case, the voltage difference between the second electrode and the first electrode of the light-emitting sub-pixel 20 is less than the turn-on voltage Von, the light-emitting sub-pixel does not emit light, and a light-emitting current flowing through the light-emitting sub-pixel 20 is basically 0. When the EM signal jumps from a high level to a low level, the potential of the first electrode of the light-emitting sub-pixel 20 rapidly drops to ELVSS. In this case, the light-emitting sub-pixel 20 emits light normally, and the light-emitting current flowing through the light-emitting sub-pixel 20 is associated with the data voltage written into the pixel driving circuit 21.

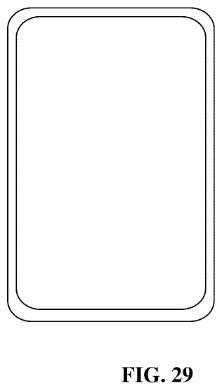

An embodiment of the present application further provides a display apparatus. Referring to FIG. 29, the display apparatus may be a personal computer (PC), a TV, a monitor, a mobile terminal, a tablet computer, a wearable device, or the like. The display apparatus may include the display panel provided in the embodiments of the present application.

The functional block shown in the above structural block diagram may be implemented as hardware, software, firmware, or a combination thereof. When implemented in hardware, it may be, for example, an electronic circuit, an application specific integrated circuit (ASIC), appropriate firmware, a plug-in, a function card, or the like. When implemented in software, elements according to the present application are programs or code segments used to perform required tasks. The program or code segments may be stored in a machine-readable medium or transmitted over a transmission medium or communication link through a data signal carried in a carrier wave. The “machine-readable medium” may include any medium capable of storing or transmitting information. Examples of the machine-readable medium include an electronic circuit, a semiconductor memory device, a random access memory (ROM), a flash memory, an erasable ROM (EROM), a floppy disk, a compact disc read-only memory (CD-ROM), an optical disk, a hard disk, a fiber optic medium, a radio frequency (RF) link, and the like. The code segments may be downloaded via a computer network such as the Internet, an intranet, or the like.

It is to be noted that herein, the terms “include”, “comprise,” or any variants thereof are intended to cover a non-exclusive inclusion, such that processes, methods, articles, or devices, including a series of elements, include not only those elements that have been listed, but also other elements that have not specifically been listed or the elements intrinsic to these processes, methods, articles, or devices.

While the principle and implementations of the present application are described in the above specific examples, those examples are only described to facilitate understanding the method and core idea of the present application. Those mentioned above are only some preferred embodiments of the present application. It should be noted that due to limitation of literal expression and objectively infinite specific structures, those of ordinary skill in the art may make various improvements, modifications or variations, and combine the above technical features in appropriate manners, without departing from the principle of the present application; however, those improvements, modifications, variations, or combinations, or direct application of the concept and technical solutions of the present application to other scenarios without improvement shall be deemed as falling into the scope of protection of the present application.

What is claimed is:

1. A power selection circuit, comprising a voltage signal line, the voltage signal line being configured to transmit a voltage signal to a first electrode of a light-emitting sub-pixel, and control at least two groups of light-emitting sub-pixels to emit light group by group;
wherein one group of light-emitting sub-pixels comprises at least one row of light-emitting sub-pixels or at least one row of light-emitting sub-pixel units, and one of the light-emitting sub-pixel units comprises at least two different light-emitting sub-pixels.

2. The power selection circuit of claim 1, wherein a voltage signal less than a difference between a second electrode voltage of the light-emitting sub-pixel and a turn-on voltage of the light-emitting sub-pixel is intermittently transmitted in the voltage signal line.

3. The power selection circuit of claim 2, wherein the voltage signal less than the difference between the second electrode voltage of the light-emitting sub-pixel and the turn-on voltage of the light-emitting sub-pixel and a voltage signal greater than the difference between the second electrode voltage of the light-emitting sub-pixel and the turn-on voltage of the light-emitting sub-pixel are transmitted in the voltage signal line in a time-sharing manner.

4. The power selection circuit of claim 1, wherein at least part of the at least two different light-emitting sub-pixels are located in different rows.

5. The power selection circuit of claim 1, further comprising a first signal module, the voltage signal line comprising a first voltage signal line;
a first terminal of the first signal module being connected to the first voltage signal line, a second terminal of the first signal module being connected to first electrodes of one group of light-emitting sub-pixels, and a control terminal of the first signal module being connected to a first control signal line;
wherein in a light-emitting stage, a voltage signal transmitted in the first voltage signal line is less than a difference between a second electrode voltage of the light-emitting sub-pixel and a turn-on voltage of the light-emitting sub-pixel.

6. The power selection circuit of claim 5, further comprising a second signal module, the voltage signal line comprising a second voltage signal line;
a first terminal of the second signal module being connected to the second voltage signal line, a second terminal of the second signal module being connected to the second terminal of the first signal module, and a control terminal of the second signal module being connected to a second control signal line;
wherein in a non-light-emitting stage, a voltage signal transmitted in the second voltage signal line is greater than the difference between the second electrode voltage of the light-emitting sub-pixel and the turn-on voltage of the light-emitting sub-pixel.

7. The power selection circuit of claim 6, wherein the first signal module comprises a first transistor, a first electrode of the first transistor is connected to the first voltage signal line, a second electrode of the first transistor is connected to the first electrodes of one group of light-emitting sub-pixels, and a gate of the first transistor is connected to the first control signal line; and
the second signal module comprises a second transistor, a first electrode of the second transistor is connected to the second voltage signal line, a second electrode of the second transistor is connected to the second electrode of the first transistor, and a gate of the second transistor is connected to the second control signal line.

8. The power selection circuit of claim 7, wherein a type of the first transistor is opposite to a type of the second transistor, and a signal in the first control signal line and a signal in the second control signal line are a same signal;
the first control signal line and the second control signal line are a same signal line.

9. The power selection circuit of claim 7, wherein a type of the first transistor is the same as a type of the second transistor, and a signal in the first control signal line and a signal in the second control signal line are opposite signals.

10. The power selection circuit of claim 6, wherein a signal in the first control signal line and a signal in the second control signal line are both step-by-step shift signals;
a signal duty cycle in the first control signal line and a signal duty cycle in the second control signal line are both adjustable.

11. A display panel, comprising the power selection circuit of claim 1, and
a plurality of groups of light-emitting sub-pixels arranged in an array, each group of light-emitting sub-pixels comprising at least one row of light-emitting sub-pixels or at least one row of light-emitting sub-pixel units, one of the light-emitting sub-pixel units comprising at least two different light-emitting sub-pixels, first electrodes of the light-emitting sub-pixels in a same group being electrically connected, and first electrodes of the light-emitting sub-pixels in different groups being insulated from each other;
wherein one power selection circuit is connected to the first electrodes of one group of light-emitting sub-pixels.

12. The display panel of claim 11, wherein the first electrodes of the light-emitting sub-pixels in the light-emitting sub-pixels or the light-emitting sub-pixel units in adjacent rows in a same group are electrically connected through an isolation pillar.

13. The display panel of claim 12, wherein a partition groove is provided in the isolation pillar between the light-emitting sub-pixels in the light-emitting sub-pixels or the light-emitting sub-pixel units in different groups and adjacent rows, the partition groove being configured to divide the isolation pillar into a first sub-isolation pillar and a second sub-isolation pillar, the first sub-isolation pillar and the second sub-isolation pillar being insulated, the light-emitting sub-pixels in one row of the light-emitting sub-pixels or the light-emitting sub-pixel units in different groups and adjacent rows are electrically connected to the first sub-isolation pillar, and the light-emitting sub-pixels in the other row of the light-emitting sub-pixels or the light-emitting sub-pixel units in different groups and adjacent rows are electrically connected to the second sub-isolation pillar.

14. The display panel of claim 12, wherein the power selection circuit is electrically connected to the isolation pillar;
the isolation pillar comprises a metal isolation pillar; and
in a direction perpendicular to an extension direction of a single group of the light-emitting sub-pixels, a cross-sectional shape of a conductive part of the isolation pillar comprises a T shape or an inverted trapezoid.

15. The display panel of claim 11, wherein the display panel comprises a display region and a non-display region, the light-emitting sub-pixels are located in the display region, and the power selection circuit is located in the non-display region.

16. The display panel of claim 15, wherein the non-display region is located on at least one side of the display region.

17. The display panel of claim 16, wherein the non-display region is located on two opposite sides of the display region, and the non-display region on each side comprises the power selection circuit.

18. The display panel of claim 15, wherein the first electrodes of the light-emitting sub-pixels in a same row of light-emitting sub-pixels or light-emitting sub-pixel units are connected to a plurality of power selection circuits.

19. The display panel of claim 18, wherein the first electrodes of the light-emitting sub-pixels in a same row of light-emitting sub-pixels or light-emitting sub-pixel units are connected to two power selection circuits, and in the two power selection circuits connected to the first electrodes of the light-emitting sub-pixels in a same row of light-emitting sub-pixels or light-emitting sub-pixel units, one of the power selection circuits is located in the non-display region on one side of the display region, and the other of the power selection circuits is located in the non-display region on the opposite side of the display region.

20. A display apparatus, comprising the display panel of claim 11.
